(19) United States
(12) Patent Application Publication
(10) Pub. No.: US 2024/0378356 A1
(43) Pub. Date: Nov. 14, 2024

(54) OPTIMIZED METHOD FOR EVALUATING THE CONNECTION QUALITY OF TWO TUBULAR COMPONENTS

(71) Applicant: VALLOUREC OIL AND GAS FRANCE, Aulnoye-Aymeries (FR)

(72) Inventors: Dominique COURTIN, Meudon (FR); Nicolas BAUDET, Meudon (FR); Florian GARDIN, Meudon (FR)

(73) Assignee: VALLOUREC OIL AND GAS FRANCE, Aulnoye-Aymeries (FR)

(21) Appl. No.: 18/691,940

(22) PCT Filed: Sep. 15, 2022
(86) PCT No.: PCT/FR2022/051739

§ 371 Date: Mar. 14, 2024

(30) Foreign Application Priority Data
Sep. 28, 2021 (FR) 21 10213

(51) Int. Cl. G06F 30/28

(52) U.S. Cl. CPC G06F 30/28

(57) ABSTRACT

A method for connecting threaded portions of a first tubular component and a second tubular component, including the obtaining of a make-up graph. The method further includes the evaluation of the connection quality of the first and second tubular components, on the basis of first and second models, by acceptance or rejection of the make-up graph obtained and assignment of a connection status respectively representing the conforming or non-conforming state of the connection of the first and second tubular components.

The present invention generally relates to threaded tubular components and, more specifically, to a method for connecting a threaded portion of a first tubular component to a threaded portion of a second tubular component.

More particularly, the invention relates to a method for evaluating the conformity of the connection of a threaded portion of a first tubular component to a threaded portion of a second tubular component.

In the field of oil and gas production, whether in an offshore or onshore facility that carries out well drilling and production operations, the operations carried out include the connection of tubular components to each other and the lowering thereof into the wells in order to form drill strings or oil or gas production strings.

A male or female threaded portion positioned at one end of a first tubular component can be directly connected to a complementary threaded portion of a second tubular component.

In another scenario, the first and second tubular components can be indirectly connected by means of an intermediate tubular component, such as a joint.

The tubular components are assembled under defined constraints in order to meet the tightening and sealing requirements imposed by operating conditions, in order to ensure the integrity of the assembly during its use throughout its service life.

However, it can be the case that the connection is not correctly made, which can result in sealing defects in the line, or even damage the tubular components or lead to the premature separation thereof.

The quality of the make-up thus has a direct influence on the sealing and longevity of the assembly of tubular components. It is therefore necessary to evaluate the quality of the connection made by accepting or rejecting the conformity of the make-up.

Conventionally, the tools intended for connecting tubular components comprise sensors configured to determine the torque applied during make-up and the number of revolutions of the first tubular component relative to the second tubular component. These tools make it possible to plot a graph showing the change in the value of the torque as a function of the number of revolutions made during assembly, which is generally referred to as a “make-up graph”.

Solutions for evaluating the connection quality of two tubular components consist of the development of the make-up graph by a competent person.

However, this person can then be subject to the risks relating to their presence on the platform on which the connection is being made. In addition, some criteria are not easy for the operator to interpret. Further, this type of evaluation depends on the skills of the operator and is not therefore satisfactorily reliable.

Other known methods for evaluating the connection quality of two tubular components are automated and based on machine learning. They rely on the analysis of a number of parameters of the make-up graph obtained.

On the basis of the value of these parameters, a connection status of the tubular components, representing the conforming or non-conforming state, is associated with the make-up graph, which makes it possible to define whether the connection either conforms or does not conform with the required specifications.

However, the probability of an unsatisfactory evaluation remains significant. There is a need to reduce this probability of an unsatisfactory evaluation. Some of the non-conforming connections might be incorrectly deemed to have been made successfully, and vice versa. A poorly made connection can have dramatic consequences for safety or the environment. There is a need to improve the techniques for evaluating the connection of tubular components in order to improve the integrity of the string formed.

The invention therefore aims to overcome these drawbacks and relates to a method for connecting threaded tubular components resulting in an accurate and reliable evaluation of the quality of the connection.

A method is thus proposed for connecting a first threaded portion of a first tubular component and a second threaded portion of a second tubular component, said first threaded portion and second threaded portion having a predetermined optimum torque corresponding to a torque to be reached in a final connection position, the connection method comprising:
engaging the first threaded portion on the second threaded portion;
rotating the first tubular component relative to the second tubular component in order to make up the threaded portions:
obtaining a make-up graph showing the torque applied during the make-up of the first threaded portion on the second threaded portion to the final position as a function of an amount of relative rotation between the first and second tubular components, for example as a function of the number of revolutions made by the first tubular component relative to the second tubular component.

The method further comprises the evaluation of the connection quality of the first and second tubular components, on the basis of a first model and a second model, by acceptance or rejection of the make-up graph obtained and assignment of a connection status respectively representing the conforming or non-conforming state of the connection of the first and second tubular components:
the first model being configured to reject the make-up graph when at least one primary numeric variable of the make-up graph obtained is outside a range of reference values associated with said at least one primary numeric value, said range of reference values representing a conforming state of the connection of the first and second tubular components; and
the second model being based on an algorithm driven by machine learning on the basis of elementary variables of reference make-up graphs, said reference make-up graphs being stored for example in a database, said second model being configured to evaluate the connection quality of the first and second tubular components as a function of said elementary variables when the make-up graph obtained has first been accepted by the first model.

The first model based on numeric primary variables allows the rejection of graphs in a way that can be fully interpreted, with precise identification of the cause of the rejection. The second model, based on an algorithm driven by machine learning, offers a summary of the history of the make-up curves deemed conforming or non-conforming by expert appraisal. Typically, the second model can be a decision algorithm based on a numeric model defined by learning.

To make it possible to drive the model, the make-up graph and the make-up parameters must be reduced to a list of numeric variables, referred to as elementary variables, correlated with the acceptance or rejection of the connection. The second model does not therefore strictly speaking use explicit criteria, but elementary variables that each represent a characteristic of the graph (for example an area under the curve, a torque difference between two points, a slope, etc.).

The combination of the first model and the second model thus offers satisfactory performance for the evaluation of the conformity of the connection obtained.

Preferably, learning takes place by segmentation of a population of initial reference graphs, the conformity of which is for example determined by human expert appraisal. A first part of this population is used for the learning itself by an algorithm, for example a random forest algorithm. Another part of this population is used to measure the relevance of the predictions of the algorithm trained in this way. This segmentation can be reiterated in order to confirm the performance of the model statistically. The second model thus makes it possible to detect with a good level of accuracy almost all of the graphs historically rejected by the experts in a way that complements the first model. The second model detects significantly more historical rejections as it explicitly tries to reproduce the historical labelling and not just to apply rules such as those applied by the first model.

However, unlike the first model, the decisions of the second model are difficult to interpret, so that it is difficult to known why a graph is rejected by the second model. The make-up graph is thus preferably evaluated by the first model initially and, if the make-up graph obtained by the first model is classified as conforming by the first model, the second model then evaluates said make-up graph obtained. This strategy empirically allows a good balance between detection performance, interpretability of the decision and robustness of the model.

Advantageously, the primary numeric variables comprise one or more of the following variables: the torque in the final position, the torque in a shoulder position in which respective shoulders of the first and second tubular components come into contact, the amount of relative rotation between the first and second tubular components between the shoulder position and the final position, for example the number of revolutions between the shoulder position and the final position, the slope of the graph between the shoulder position and the final position, the torque in a sealing position in which the respective sealing seats of the first and second tubular components come into contact, and/or the amount of relative rotation between the first and second tubular components between the sealing position and the shoulder position, for example the number of revolutions between the sealing position and the shoulder position.

Preferably, some of the reference make-up graphs, for example the reference graphs of the database prior to any learning by the second model, are associated with a conforming or non-conforming state of the connection by human expert appraisal. Further, some of the reference make-up graphs, for example the reference graphs of the database obtained by learning by means of the second model, are associated with a conforming or non-conforming state of the connection by learning without the use of human expert appraisal.

According to one embodiment, the elementary variables comprise one or more secondary numeric variables, the second model evaluating the connection quality of the first and second tubular components as a function of one or more of said secondary numeric variables, said one or more secondary numeric variables being calculated on the basis of a respective primary numeric variable and minimum and maximum reference values, said minimum and maximum reference values delimiting the range of reference values associated with said primary numeric variable, said one or more secondary numeric variables being calculated according to the following equation:

$$B = \frac{( A - {A}_{min} )}{( {A}_{max} - {A}_{min} )}$$

where: B is said secondary numeric variable: A is a primary numeric variable: Aₘᵢₙ is the minimum reference value equal to the lower limit of the range of reference values associated with said primary numeric variable; and Aₘₐₓ is the maximum reference value equal to the upper limit of the range of reference values associated with said primary numeric variable.

Preferably, the elementary variables comprise one or more standardized variables. Preferably, the second model evaluates the connection quality of the first and second tubular components on the basis of one or more standardized variables calculated as a function of a respective primary numeric variable, said primary numeric variable representing a torque, said one or more standardized variables being equal to the ratio of the corresponding primary numeric variable to the optimum torque.

Advantageously, the elementary variables comprise a sum of the torque losses between two successive points of the graph. Preferably, the second model can evaluate the connection quality of the first and second tubular components as a function of a standardized value of the sum of the torque losses between two successive points of the make-up graph obtained, said standardized value being equal to the ratio of said calculated sum of the torque losses to the optimum torque.

Advantageously, the elementary variables comprise a gradient between the shoulder position and the final position. Preferably, the second model can evaluate the connection quality of the first and second tubular components as a function of the variation of the gradient between the shoulder position and the final position of the make-up graph obtained.

Advantageously, the elementary variables comprise a maximum torque loss value between two successive points of the graph, said two successive points being situated between the sealing position and the shoulder position and/or between the shoulder position and the final position. Preferably, the second model can evaluate the connection quality of the first and second tubular components as a function of a standardized value of the maximum torque loss value between said two successive points of the make-up graph obtained, the standardized value being equal to the ratio of said maximum value to the optimum torque.

Advantageously, the primary numeric variables comprise a make-up speed. Preferably, the first model can evaluate the connection quality of the first and second tubular components as a function of the make-up speed on connection of the first and second tubular components.

According to one feature, the primary numeric variables comprise a loss of linearity of the graph between the shoulder position and the final position. Preferably, the first model can evaluate the connection quality of the first and second tubular components as a function of the loss of linearity obtained between the shoulder position and the final position for the make-up graph obtained.

Advantageously, the primary numeric variables comprise a maximum torque loss value between two successive points of the graph, said two successive points being situated between the shoulder position and the final position. Preferably, the first model can evaluate the connection quality of the first and second tubular components as a function of a maximum torque loss value between two successive points of the make-up graph obtained, said two successive points being situated between the shoulder position and the final position.

Advantageously, the primary numeric variables comprise an amount of relative rotation between the first and second tubular components, for example as a number of revolutions, during a torque loss occurring between the shoulder position and the final position. Preferably, the first model can evaluate the connection quality of the first and second tubular components as a function of the amount of relative rotation between the first tubular component and the second tubular component during a torque loss occurring between the shoulder position and the final position.

Advantageously, the primary numeric variables comprise an amount of relative rotation, for example as a number of revolutions, between the first and second tubular components between an engagement position and the final position, said engagement position being prior to the relative rotation between the first tubular component and the second tubular component. Preferably, the first model evaluates the connection quality of the first and second tubular components as a function of the amount of relative rotation between the first tubular component and the second tubular component between the engagement position and the final position.

Advantageously, the primary numeric variables comprise a maximum torque before the sealing position. Preferably, the first model can evaluate the connection quality of the first and second tubular components as a function of the value of a maximum torque of the make-up graph obtained before the sealing position, the make-up graph obtained being rejected by the first model when said maximum torque value is greater than 10% of the optimum torque.

Preferably, the second model includes one or more rejection criteria of the first model. In other words, the elementary variables comprise one or more primary numeric variables.

Further aims, advantages and features will become apparent from the following description, given solely by way of illustrative example with reference to the appended drawings, in which:

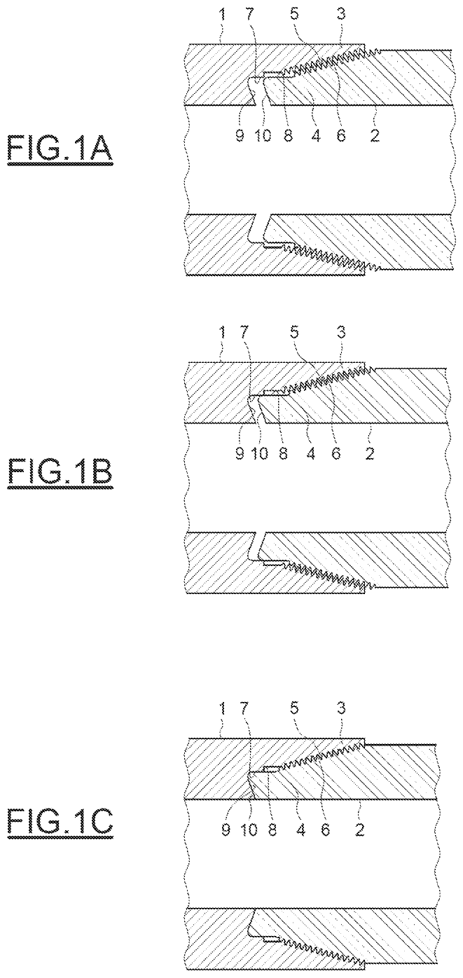

FIG. 1A

FIG. 1B

and

FIG. 1C are cross-sectional views of first and second tubular components to be connected, in a make-up position, a sealing position and a shoulder position respectively; and

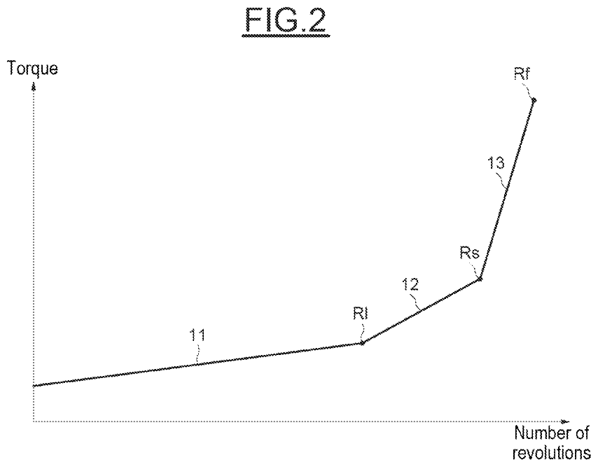

FIG. 2 illustrates a make-up graph showing the torque applied during the connection of first and second tubular components as a function of the number of revolutions made by the first tubular component relative to the second tubular component.

FIGS. 1A, 1B and IC illustrate different steps of the connection of a first tubular component 1 to a second tubular component 2.

In the example shown, the tubular component 1 is a sleeve joint, configured to allow the connection of the second tubular component 2 to a third tubular component, not shown.

The first and second tubular components 1 and 2 comprise a threaded portion, 3 and 4 respectively, advantageously positioned at one of their ends. The thread 5 of the threaded portion 3 and the thread 6 of the threaded portion 4 are configured to interact.

In addition, the first tubular component 1 comprises a first sealing seat 7, and the second tubular component 2 comprises a second sealing seat 8. The sealing seats are formed by a surface intended to seal the assembly of the tubular components 1 and 2 when they are connected.

The first tubular component 1 further comprises a first shoulder 9, and the second tubular component 2 comprises a second shoulder 10. The shoulders 9 and 10 form a stop for stopping make-up.

The sealing seats 7 and 8, and the shoulders 9 and 10, are respectively configured to interact.

Tubular components exist that do not comprise a stop. Tubular components also exist that do not comprise sealing seats. Tubular components also exist that do not comprise stops or sealing seats. The invention is suitable for being applied partially to the connection of these types of components, for the graph portions between the start of connection and contact between the sealing seats, for the graph portion between the contact between the sealing seats and the end of connection, or between the start of connection and the end of connection without there being any contact between sealing seats or stops during connection.

In order to connect the two tubular components 1 and 2, the connection method firstly comprises engaging the first tubular component 1 on the second tubular component 2. More particularly, the connection method comprises engaging the first threaded portion 3 in the second threaded portion 4.

In order to make up the threaded portions 3 and 4, the first tubular component 1 is rotated relative to the second tubular component 2.

The tool used to make the connection is a make-up wrench. This make-up wrench is provided with grippers and motors to rotate the first and second tubular components 1 and 2 relative to each other. The make-up wrench is also provided with sensors to measure the number of revolutions applied and the make-up torque applied. These sensors are connected to an electronic unit making it possible to store the data relating to the torques and rotations applied and relating to the assembly during the operation. This electronic unit is connected to a processing unit comprising a processing algorithm. The processing unit is also provided with a user interface to display an evaluation result and/or a make-up graph obtained during a connection.

The method thus further comprises obtaining a set of points forming a make-up graph representing the torque applied during the make-up of the first tubular component 1 to a final position as a function of the number of revolutions made by the first tubular component 1 relative to the second tubular component 2.

The general profile of the graph obtained, referred to as the torque/revolutions graph, representing the torque applied during make-up as a function of the number of revolutions made, is illustrated in FIG. 2. It can be seen that the graph obtained comprises three separate portions with different slopes.

The first portion 11 corresponds to the engagement of the first tubular component 1 on the second tubular component 2 and then to the make-up of the threaded portions 3 and 4, as illustrated in FIG. 1A. The threads 5 and 6 gradually come into contact, resulting in increasingly high torque applied.

At the landing point RI, the first sealing seat 7 of the first tubular component 1 comes into contact with the second sealing seat 8 of the second tubular component 2. The tubular components 1 and 2 are then in a position referred to as the sealing position, illustrated in FIG. 1B.

The significant friction caused by the coming into contact of the sealing seats 7 and 8 results in a change in slope and in particular an increase in the torque applied per rotation, defining a second portion 12 of the graph obtained.

Continuing to make up the threaded portions 3 and 4, the rotation of the first tubular component 1 relative to the second tubular component 2 then leads to a shoulder point Rs. The tubular components 1 and 2 are then in a position referred to as the shoulder position, illustrated in FIG. 1C, in which the first shoulder 9 of the first tubular component 1 comes into contact with the second shoulder 10 of the second tubular component 2. The increased friction between the surfaces of the respective shoulders 9 and 10 is added to the friction resulting from the contact between the threads 5 and 6 and the friction between the sealing seats 7 and 8, which results in another change in slope and a significant increase in the torque applied, defining a third portion 13 of the graph obtained, extending to a final point Rf at which the tubular components have reached the final position.

In the present invention, final position is given to mean a position of the first and second tubular components 1 and 2 in which a maximum make-up torque is applied and the connection is complete.

The landing point Rl, the shoulder point Rs, the final point Rf, and a slope factor S between the shoulder point Rs and the final point Rf of the make-up graph are parameters of the make-up graph that can be taken into account for determining the conformity of the connection of the first and second tubular components 1, 2. The value of each of these parameters depends on the type of the tubular components to be connected.

The slope factor S can be calculated on the basis of the torque Ts at the shoulder point, the torque Tf at the final point and an optimum torque T*. The slope factor is defined by the slope between the shoulder position and the final position, divided by the optimum torque T*, as expressed by the following equation:

$$s = \frac{Tf - Ts}{{T}^{*} ( Rf - Rs )}$$

Optimum torque T* is given to mean a predetermined torque to be reached in the final position, which is specific to the model of tubular components and model of joint to be connected.

The connection method comprises the evaluation of the connection quality of the first and second tubular components 1, 2 on the basis of first and second make-up graph rejection models.

The first and second models accept or reject the make-up graph obtained as a function of rejection criteria. When the make-up graph obtained is accepted, a connection status representing the conforming state of the connection of the first and second tubular components 1 and 2 is assigned to the make-up graph, and when the make-up graph obtained is rejected, a connection status representing the non-conforming state of the connection of the first and second tubular components 1 and 2 is assigned to the make-up graph.

The automation resulting from the evaluation of the connection quality of the tubular components by the first and second models makes it possible to eliminate the human factor during the evaluation of the conformity of a connection, and thus increase the accuracy of the evaluation.

The first model is configured to reject the make-up graph when the value of at least one primary numeric variable A of the make-up graph obtained deviates from a range of reference values characteristic of a conforming state of the connection of the first and second tubular components 1, 2.

The first model can rely on an algorithm.

The second model is based on an algorithm driven by machine learning or artificial intelligence. In particular, the algorithm is driven on the basis of elementary variables of reference make-up graphs stored in a database.

The elementary variables considered by the algorithm of the second model each represent a characteristic of the make-up graph.

When the make-up graph obtained has first been accepted by the first model, the second model in turn evaluates the connection quality of the first and second tubular components 1 and 2 in order to confirm or deny the acceptance of the make-up graph by the first model.

In other words, the evaluation of the connection quality of the first and second tubular components 1, 2 is conducted, in a first step, by the first rejection model and then, in a second step, by the second model, if the make-up graph is first accepted by the first model.

Primary numeric variables A can be determined on the make-up graph on the basis of the following parameters: the landing point RI, the shoulder point Rs, the final point Rf, and/or the slope factor S between the shoulder point Rs and the final point Rf of the make-up graph.

In the example illustrated, the primary numeric variables A considered by the first model include: the torque Tf in the final position, the torque Ts in the shoulder position, the number of revolutions ΔR_{s-f} between the shoulder position and the final position, and the slope factor S.

According to one embodiment, other primary numeric variables A can be considered, such as the torque Tl in a sealing position and the number of revolutions ΔRₗ₋ₛ between the sealing position and the shoulder position.

For each of the primary numeric variables A considered, a range of reference values is determined, delimited by a minimum reference value Aₘᵢₙ and a maximum reference value Aₘₐₓ. The range of reference values represents a conforming state of the connection of the first and second tubular components 1, 2.

According to one example, the minimum reference value Aₘᵢₙ and the maximum reference value Aₘₐₓ can be determined, for each type of tubular component and model of joint to be connected, on the basis of reference graphs stored in a database and associated with a connection status representing a conforming or non-conforming state of the connection of reference first and second tubular components.

The reference graphs for which the connection was successfully made are associated with a conforming state and, conversely, the reference graphs for which the connection failed are associated with a non-conforming state.

Preferably, the reference make-up graphs are stored in a database. These reference graphs of the database are associated with a conforming or non-conforming state of the connection, preferably by human expert appraisal. An expert or any other competent person can accept the connection of the reference tubular components by associating “conforming” status with the reference graph obtained, if they find that the connection was made successfully. Conversely, the expert rejects the connection of the reference tubular components by associating “non-conforming” status with the reference graph obtained, if they find that the connection failed. It is thus possible to obtain a reliable, extensive database.

In the example illustrated, the first model is configured to reject the make-up graphs when the torque Tf in the final position, the torque Ts in the shoulder position, the number of revolutions ΔR_{s-f} between the shoulder position and the final position, and the slope factor S are less than the minimum reference value Aₘᵢₙ with which they are respectively associated, or greater than the maximum reference value Aₘₐₓ with which they are respectively associated.

In order to increase the accuracy of the evaluation of the connection, additional rejection criteria can be incorporated into the first model.

Advantageously, the first model can evaluate the connection quality of the first and second tubular components 1, 2 as a function of the make-up speed. Too high a speed, in particular in the shoulder position, can reflect a connection defect.

The make-up graph is preferably rejected when the make-up speed is greater than a predetermined threshold value, for example equal to five revolutions per minute.

According to one feature, a rejection criterion of the first model can be based on the determining of a loss of linearity between the shoulder position and the final position. A loss of linearity can in particular reflect plastic deformation and slipping.

A linear interpolation can be carried out, by plotting a straight line passing through the 25% index and the 75% index between the shoulder point Rs and the final point Rf. The maximum distance between the make-up graph obtained during the connection method and the straight line is then calculated.

The loss of linearity can be calculated by dividing the mean deviation of the graph relative to the linear interpolation by the optimum torque T*. An absolute value of the mean deviation will preferably be calculated by the algorithm driven by machine learning so that the oscillations from the linear interpolation result in a high coefficient and are easier to determine.

The make-up graph is rejected when the distance obtained by this loss of linearity is greater than a predetermined threshold value.

Advantageously, the first model can evaluate the connection quality of the first and second tubular components 1, 2 as a function of a maximum torque loss value between two successive points of the make-up graph obtained between the shoulder position and the final position.

Determining a maximum torque loss value is particularly advantageous for detecting connection defects linked to slipping or sliding, and can generally reflect the appearance of noises in the power cable.

Maximum torque loss value is given to mean the greatest torque loss determined on the make-up graph.

Advantageously, a rejection criterion of the first model can be based on the number of revolutions made during a torque loss occurring between the shoulder position and the final position.

Some brief torque losses can simply correspond to an artefact. However, when the number of revolutions made during a torque loss is greater than a predetermined threshold value, the torque loss can be interpreted as the occurrence of a defect resulting in a non-conforming state of the connection.

Advantageously, the first model can also evaluate the connection quality of the first and second tubular components 1, 2 as a function of the number of revolutions Rf made in the final position in order to reject graphs that are too short, reflecting a non-conforming state of the connection.

The make-up graph is for example rejected when the number of revolutions Rf made in the final position is less than a predetermined threshold value, for example equal to one revolution.

Advantageously, the first model evaluates the connection quality of the first and second tubular components as a function of the value of a maximum torque before the sealing position, the make-up graph obtained being rejected by the first model when said maximum torque value is greater than 10% of the optimum torque T*.

The first model is a combination of numeric criteria representing unambiguous reasons for rejecting make-up graphs. Each of these rejection criteria is calculated on the basis of a numeric criterion and a minimum or maximum threshold on this numeric criterion. This first model is adaptable and makes it possible to identify the rejection scenarios corresponding to the most frequent problems that occur during the connection of two tubular components 1, 2. It is also fully interpretable, with the causes for rejection and the level by which the threshold is exceeded being identifiable.

Preferably, when the first model rejects the make-up graph, the operator is notified of an explicit reason by indication of the rejection criterion on which the assignment of a status representing a non-conforming state is based.

In addition, the second model can preferably evaluate the connection quality of the first and second tubular components as a function of one or more secondary numeric variables B, each calculated on the basis of a primary numeric variable A, and minimum and maximum reference values Aₘᵢₙ, Aₘₐₓ delimiting the range of reference values according to the following equation:

$$B = \frac{( A - {A}_{min} )}{( {A}_{max} - {A}_{min} )}$$

where: B is a secondary numeric variable: A is a primary numeric variable: Aₘᵢₙ is the minimum reference value of the primary numeric variable; and Aₘₐₓ is the maximum reference value of the primary numeric variable.

The secondary numeric variables B calculated make it possible to measure, more easily and with greater sensitivity, a deviation of the primary numeric variable A with respect to the range of reference values delimited by the minimum reference value Aₘᵢₙ and the maximum reference value Aₘₐₓ. When the secondary numeric variable B calculated is less than 0 or greater than 1, this means that the primary variable A is not included in the range of reference values and the algorithm rejects the make-up graph, which is then associated with a non-conforming state of the connection.

This results in finer, more reliable discrimination relating to the make-up quality, for a variety of joint models.

In the example illustrated, the secondary variables B are calculated on the basis of the torque Tf in the final position, the torque Ts in the shoulder position, the number of revolutions ΔR_{s-f} between the shoulder position and the final position, and the slope factor S.

For example, the secondary variable Bf linked to the final torque is calculated according to the following equation:

$$Bf = \frac{( Tf - {Tf}_{min} )}{( {Tf}_{max} - {Tf}_{min} )}$$

where: Bf is a secondary variable linked to the final torque: Tf is the final torque: Tfₘᵢₙ is the minimum reference value of the final torque; and Tfₘₐₓ is the maximum reference value of the final torque.

Preferably, the second model can also evaluate the connection quality of the first and second tubular components 1, 2 on the basis of one or more standardized variables C. A standardized variable C is calculated as a function of a primary numeric variable A representing a torque, the standardized variable being equal to the ratio of the primary numeric variable A to the optimum torque T* as defined by the following equation:

$$C = \frac{A}{{T}^{*}}$$

where: C is a standardized variable: A is a primary variable; and T* is the optimum torque.

For example, the standardized variable linked to the final torque is calculated according to the following equation:

$$Cf = \frac{Tf}{{T}^{*}}$$

where: Cf is the standardized variable linked to the final torque: Tf is the final torque; and T* is the optimum torque.

In the example illustrated, the standardized variables C are calculated on the basis of the torque Tf in the final position, the torque Ts in the shoulder position, the torque Tl in the sealing position, the delta torque ΔTₗ₋ₛ between the sealing position and the shoulder position, and the delta torque ΔT_{s-f} between the shoulder position and the final position.

The delta torque ΔTₗ₋ₛ between the sealing position and the shoulder position corresponds to the difference in the torque value measured between the sealing position and the shoulder position.

Preferably, the second model can reject the make-up graph as a function of the sum of the torque losses between two successive points of the make-up graph obtained. This makes it possible in particular to detect thread interference. In this regard, a standardized value will preferably be calculated and defined by said sum of the torque losses calculated divided by the predetermined optimum torque T*.

Advantageously, the second model can evaluate the connection quality of the first and second tubular components as 1, 2 a function of the variation of the gradient after the shoulder position on the make-up graph obtained.

The variation of the gradient is equal to the deviation from the defined list by the slopes between the shoulder position and the final position on the make-up graph obtained divided by the optimum torque T*.

Advantageously, the second model can evaluate the connection quality of the first and second tubular components 1, 2 as a function of a maximum torque loss value between two successive points of the make-up graph obtained between the sealing position and the shoulder position and/or between the shoulder position and the final position.

Even more advantageously, the rejection criterion based on the maximum torque loss can be evaluated on the basis of a standardized value equal to the ratio of said maximum torque loss value to the optimum torque T*.

The rejection criterion based on the maximum torque loss can also be evaluated on the basis of a standardized value equal to the ratio of said maximum torque loss value to the shoulder torque Ts.

Further, the second model can evaluate the connection quality of the first and second tubular components 1, 2 as a function of the value of a maximum torque before the sealing position and/or between the sealing position and the shoulder position, the make-up graph being rejected by the second model when said maximum torque value is greater than 10% of the optimum torque T*.

Preferably, a standardized value is defined by said maximum torque divided by the shoulder torque Ts. A high value can reflect a joint problem.

Further, a rejection criterion of the second model can be based on the value of the area defined between the graph and the x-axis, that is, the number of revolutions, for the last two revolutions divided by the optimum torque T*. This makes it possible in particular to reject make-up graphs that do not have a landing point RI or a shoulder point Rs.

The second model is based on an algorithm driven by machine learning. To make it possible to drive the model, the make-up graph and the make-up parameters are reduced to a list of elementary variables correlated with the acceptance or rejection of the make-up. The elementary variables each represent a characteristic of the make-up graph.

Preferably, for the sake of performance, the second model includes one or more rejection criteria of the first model. Increasing the number of variables describing the graph helps the algorithm to categorize the graphs. Learning then takes place on the database of reference make-up graphs.

The method for connecting the first and second tubular components 1, 2 can comprise the establishment of a score by the second model after evaluation of the connection quality as a function of the rejection criteria specific thereto.

For example, if the score of the second model is greater than a given predetermined threshold, the make-up graph is rejected. Conversely, if the score is below the threshold, the make-up graph is accepted.

This second machine learning model thus makes it possible to detect with very good accuracy almost all of the make-up graphs rejected by the first model.

The first and second models are complementary and make it possible to detect approximately 70% and 99% of rejection scenarios respectively. This strategy for evaluating the connection quality of two tubular components empirically allows the best balance between detection performance, interpretability of the decision, and robustness of the overall model.

The combination thereof thus makes it possible to detect almost all of the non-conforming connections, in an automated manner, without human intervention.

1. A method for connecting a first threaded portion of a first tubular component and a second threaded portion of a second tubular component, said first threaded portion and second threaded portion having a predetermined optimum torque corresponding to a torque to be reached in a final connection position, the connection method comprising:
engaging the first threaded portion on the second threaded portion;
rotating the first tubular component relative to the second tubular component in order to make up the threaded portions;
obtaining a make-up graph showing the torque applied during the make-up of the first threaded portion on the second threaded portion to the final position as a function of an amount of relative rotation between the first and second tubular components;
wherein it comprises the evaluation of the connection quality of the first and second tubular components, on the basis of a first model and a second model, by acceptance or rejection of the make-up graph obtained and assignment of a connection status respectively representing the conforming or non-conforming state of the connection of the first and second tubular components;
the first model being configured to reject the make-up graph when at least one primary numeric variable of the make-up graph obtained is outside a range of reference values associated with said at least one primary numeric variable, said range of reference values representing a conforming state of the connection of the first and second tubular components; and
the second model being based on an algorithm driven by machine learning on the basis of elementary variables of reference make-up graphs, said second model being configured to evaluate the connection quality of the first and second tubular components as a function of said elementary variables when the make-up graph obtained has first been accepted by the first model.

2. The method according to claim 1, in which the primary numeric variables comprise one or more of the following variables: the torque in the final position, the torque in a shoulder position in which respective shoulders of the first and second tubular components come into contact, the amount of relative rotation between the first and second tubular components between the shoulder position and the final position (ΔR_{s-f}), the slope of the graph between the shoulder position and the final position, the torque in a sealing position in which the respective sealing seats of the first and second tubular components come into contact, and/or the amount of relative rotation between the first and second tubular components (ΔRₗ₋ₛ) between the sealing position and the shoulder position.

3. The method according to claim 2, in which the elementary variables comprise a gradient between the shoulder position and the final position, the second model evaluating the connection quality of the first and second tubular components as a function of the variation of the gradient between the shoulder position and the final position of the make-up graph obtained.

4. The method according to claim 2, in which the elementary variables comprise a maximum torque loss value between two successive points of the graph, said two successive points being situated between the sealing position and the shoulder position and/or between the shoulder position and the final position, the second model evaluating the connection quality of the first and second tubular components as a function of a standardized value of the maximum torque loss value between said two successive points of the make-up graph obtained, the standardized value being equal to the ratio of said maximum value to the optimum torque.

5. The method according to claim 2, in which the primary numeric variables comprise a loss of linearity of the graph between the shoulder position and the final position, the first model evaluating the connection quality of the first and second tubular components as a function of the loss of linearity obtained between the shoulder position and the final position for the make-up graph obtained.

6. The method according to claim 2, in which the primary numeric variables comprise an amount of relative rotation between the first and second tubular components during a torque loss occurring between the shoulder position and the final position, the first model evaluating the connection quality of the first and second tubular components as a function of the amount of relative rotation between the first tubular component and the second tubular component during a torque loss occurring between the shoulder position and the final position.

7. The method according to claim 2, in which the primary numeric variables comprise an amount of relative rotation between the first and second tubular components between an engagement position and the final position, said engagement position being prior to the relative rotation between the first tubular component and the second tubular component, the first model evaluating the connection quality of the first and second tubular components as a function of the amount of relative rotation between the first tubular component and the second tubular component between the engagement position and the final position.

8. The method according to claim 2, in which the primary numeric variables comprise a maximum torque before the sealing position, the first model evaluating the connection quality of the first and second tubular components as a function of the value of a maximum torque of the make-up graph obtained before the sealing position, the make-up graph obtained being rejected by the first model when said maximum torque value is greater than 10% of the optimum torque.

9. The method according to claim 1, in which the primary numeric variables comprise a maximum torque loss value between two successive points of the graph, said two successive points being situated between the shoulder position and the final position, the first model evaluating the connection quality of the first and second tubular components as a function of a maximum torque loss value between two successive points of the make-up graph obtained.

10. The method according to claim 1, in which some of the reference make-up graphs are associated with a conforming or non-conforming state of the connection by human expert appraisal.

11. The method according to claim 1, in which the elementary variables comprise one or more secondary numeric variables, the second model evaluating the connection quality of the first and second tubular components as a function of one or more of said secondary numeric variables, said one or more secondary numeric variables being calculated on the basis of a respective primary numeric variable and minimum and maximum reference values (Amin, Amax), said minimum and maximum reference values (Amin, Amax) delimiting the range of reference values associated with said primary numeric variable, said one or more secondary numeric variables being calculated according to the following equation:
$$B = \frac{( A - {A}_{min} )}{( {A}_{max} - {A}_{min} )}$$
where: B is said secondary numeric variable; A is a primary numeric variable; Amin is the minimum reference value equal to the lower limit of the range of reference values associated with said primary numeric variable; and Amax is the maximum reference value equal to the upper limit of the range of reference values associated with said primary numeric variable.

12. The method according to claim 1, in which the elementary variables comprise one or more standardized variables, the second model evaluating the connection quality of the first and second tubular components on the basis of one or more standardized variables calculated as a function of a respective primary numeric variable, said primary numeric variable representing a torque, said standardized variable being equal to the ratio of the corresponding primary numeric variable to the optimum torque.

13. The method according to claim 1, in which the elementary variables comprise a sum of the torque losses between two successive points of the graph, the second model evaluating the connection quality of the first and second tubular components as a function of a standardized value of the sum of the torque losses between two successive points of the make-up graph obtained, said standardized value being equal to the ratio of said sum of the torque losses calculated to the optimum torque.

14. The method according to claim 1, in which the primary numeric variables comprise a make-up speed, the first model evaluating the connection quality of the first and second tubular components as a function of the make-up speed during the connection of the first and second tubular components.

15. The method according to claim 1, in which the second model includes one or more of the rejection criteria of the first model.
